(19) United States
(12) Patent Application Publication
(10) Pub. No.: US 2006/0067055 A1
(43) Pub. Date: Mar. 30, 2006

(54) Thermally conductive composite and uses for microelectronic packaging

(76) Inventors: Kenneth H. Heffner, Tampa, FL (US); Scott G. Fleischman, Largo, FL (US); William J. Dalzell, Parrish, FL (US)

Correspondence Address: Andrew Abeyta;Honeywell International Inc., Law Dept. AB2, 101 Columbia Rd.,, Morristown, NJ, 07962, US

(21) Appl. No.: 11/239,713

(22) Filed: Sep. 29, 2005

Related U.S. Application Data
(60) Provisional application No. 60/614,949, filed on Sep. 30, 2004.
(60) Provisional application No. 60/614,948, filed on Sep. 30, 2004.

(51) Int. Cl. H05K 7/20

(52) U.S. Cl. 361/704

(57) ABSTRACT

The present invention provides thermally conductive, electrically insulating composites that can be used to help conduct heat away from a heat source such as from microelectronic structures that generate heat during use. In one aspect, the present invention relates to an electronic system comprising a microelectronic device and a thermally conductive, composite in thermal contact with the microelectronic device. The composite is derived from ingredients comprising a macrocyclic oligomer; and a thermally conductive filler comprising diamond.

### PRIORITY CLAIM

The present non-provisional Application claims priority under 35 USC §119(e) from (a) United States Provisional Patent Application having Ser. No. 60/614,949, filed on Sep. 30, 2004, by Heffner et al. and titled ELECTRONIC SYSTEMS CONTAINING THERMAL COMPOSITES, wherein said provisional application is commonly owned by the assignee of the present application and wherein the entire contents of said provisional application is incorporated herein by reference; and (b) United States Provisional Patent Application having Ser. No. 60/614,948, filed on Sep. 30, 2004, by Harmon et al. and titled THERMALLY CONDUCTIVE COMPOSITE AND USES FOR MICROELECTRONIC PACKAGING, wherein said provisional application is commonly owned by the assignee of the present application and wherein the entire contents of said provisional application is incorporated herein by reference.

### FIELD OF THE INVENTION

The present invention relates to electronic systems incorporating thermally conductive materials to help dissipate heat. More specifically, the present invention relates to such systems, wherein the thermally conductive material comprises a thermally conductive filler dispersed in a polymer matrix.

### BACKGROUND OF THE INVENTION

Electronic systems continue to progress towards higher levels of integration by incorporating advancements into microelectronic components that provide, for instance, higher speeds and/or higher storage capacity per unit volume. Although microelectronic components in general are significant heat sources, more modern counterparts of these components tend to generate more heat per unit volume than the earlier embodiments. If not appropriately dissipated, such heat can damage or even destroy the components and/or other constituents of the systems that incorporate the components. Consequently, the ability to effectively dissipate heat is a key factor limiting the ability to incorporate microelectronic advancements into a variety of different kinds of electronic systems, such as high density interconnect (HDI) product designs.

Thus, thermal management in an electronic system is a critical task to ensure system functionality as well as to maintain the reliability of key system components. Heat is mostly generated by active devices, such as processor chips. Heat dissipation from an active device has been therefore an important design consideration, particularly due to the increase in the number of circuits per unit area.

Many approaches have been proposed to address thermal management in electronic systems. Thermal conduction mechanisms have been commonly employed to dissipate the heat from an active device by attachment of a heat sink or via a heat spreader attached to a heat sink. To attach a heat sink or a heat spreader to an active device, it is necessary to use a joining material, which should possess a good thermal conductivity among other properties. Otherwise, the joint between an active device and a heat sink becomes a bottleneck in terms of heat dissipation.

Convective cooling using fans and mounted heat fins are examples of thermal management strategies that have been used. However, these strategies by themselves have proven unsatisfactory for spacecraft systems inasmuch as spacecraft are not able to rely wholly upon convective cooling strategies. Spacecraft rely more heavily upon conductive and emissive strategies.

Thermally conductive composites have been proposed to help dissipate heat away from microelectronic devices. For example, the development of thermally conductive molding materials for semiconductor technology has been well investigated. These efforts have led to conventional thermally conductive composites, such as epoxies with fused silica filler at about 50% to about 70% filler content, that display a thermal conductivity constant of about 0.5 to about 1.0 W/m*k. See also U.S. Pat. Nos. 6,596,937 and 6,114,413. These relatively modest thermal conductivity characteristics are adequate helping to dissipate heat in earlier microelectronic structures. With higher processor speeds and denser packaging designs, however, this level of performance is inadequate. Additionally, these composites tend to have relatively poor rheological properties when fluidized. This makes it more difficult from a practical perspective to closely integrate the composites with microelectronic structures containing increasingly small features. There is a distinct need to improve the performance of thermally conductive composites.

Research has demonstrated that there are significant limitations in the thermal conductivity of a composite comprising a resin carrier and a filler. See, e.g., the Neilson Model for thermal conductivity as a function of composite filler conductivity, volume fraction of filler, and geometrical parameters as described in L. E. Nielsen, (“Thermal Conductivity of Particulate-Filled Polymers,” Journal of Applied Polymer Science; 17, 3819, 1973). These limitations coupled with the fill capacity and continuity of composite blends of processable thermally conductive coatings, lead to a ceiling in the resultant thermal conductivity of these blended composites.

The microelectronics industry, especially as applied within the space industry, has been approaching a limit in affordability, effectiveness, and/or practicality with respect to thermal management strategies that can meet the demands of advanced microelectronic devices that generate increasing amounts of heat. Effective thermal management strategies are clearly needed.

### SUMMARY OF THE INVENTION

The present invention provides thermally conductive, electrically insulating composites that can be used to help conduct heat from a heat source such as from microelectronic structures that generate heat during use. The present invention is especially useful for helping to dissipate heat in electronic packaging applications.

The composite may be incorporated into electronic systems, devices, packages, components, component features, and the like in a variety of ways. For example, in one embodiment, the composite may be interposed, e.g., as an adhesive, filler, or the like, between components or component features when it is desired to provide a heat dissipating pathway between such components or component features. The composite may also be used to wholly or partially encapsulate systems, devices, components, and/or component features to help dissipate heat from the encapsulated structures.

In preferred embodiments, the present invention provides thermally conductive composite compositions of extremely low melt viscosity, convertible by polymerization to composites of higher temperature and solvent resistance.

The composites have extremely high thermal conductivity constants, being greater than about 2 W/m*K, preferably greater than about 3 W/m*K, and even greater than about 4 W/m*K. For instance, one embodiment of the present invention incorporating about 40% by volume diamond particle filler showed an initial K value of 4.21 W/mK.

Thus, in one aspect, the present invention relates to an electronic system comprising (a) a microelectronic device or power supply component(s) and (b) a thermally conductive, composite in thermal contact with the microelectronic device power supply component(s). The composite is derived from ingredients comprising a macrocyclic oligomer and a thermally conductive filler.

In another aspect, the present invention relates to a spacecraft comprising (a) a microelectronic device or power supply component(s) and a (b) thermally conductive, composite coating in thermal contact with the microelectronic device or power supply component(s). The composite is derived from ingredients comprising a macrocyclic oligomer and a thermally conductive filler.

In another aspect, the present invention relates to an electronic system, comprising a heat source comprising a microelectronic device, a heat-dissipating radiator, and a thermal pathway interconnecting the heat source and the radiator. The pathway comprises a thermally conductive, composite comprising a macrocyclic oligomer and a thermally conductive filler.

In another aspect, the present invention relates to an electronic system comprising a chassis, a heat dissipating radiator thermally coupled to the chassis, a microelectronic device mounted on the chassis wherein the device generates a heat output during use, and a thermally conductive composite encapsulating at least a portion of the microelectronic device. The composite thermally coupled to the radiator to help dissipate heat from the electronic system.

In another aspect, the present invention relates to a spacecraft comprising a thermally conductive composite. The composite is derived from ingredients comprising a macrocyclic oligomer and a thermally conductive filler.

In another aspect, the present invention relates to a method of making a microelectronic device. At least a portion of the device is encapsulated with a thermally conductive composite. The coating is derived from ingredients comprising a macrocyclic oligomer and a thermally conductive filler.

In another aspect, the present invention relates to a method of making an electronic system. Heat is dissipated from a microelectronic device at least via a thermal pathway comprising a thermally conductive composite, said composite being derived from ingredients comprising a macrocyclic oligomer and a thermally conductive filler.

In another aspect, the present invention relates to a thermally conductive paste comprising a macrocyclic, thermoplastic oligomer and a plurality of thermally conductive particles dispersed in the oligomer. In a preferred application, the particles have an average aspect ratio of about 1:1 to about 4:1 and an average length in the long dimension in the range of 0.01 to 200 micrometers.

In another aspect, the present invention relates to an electronic system comprising (a) a microelectronic device or power supply component(s) and (b) a thermally conductive, composite in thermal contact with the microelectronic device power supply component(s). The composite is derived from ingredients comprising a macrocyclic oligomer and a thermally conductive filler.

In another aspect, the present invention relates to a spacecraft comprising (a) a microelectronic device or power supply component(s) and a (b) thermally conductive, composite coating in thermal contact with the microelectronic device or power supply component(s). The composite is derived from ingredients comprising a macrocyclic oligomer and a thermally conductive filler.

In another aspect, the present invention relates to a method of making a microelectronic device. At least a portion of the device is encapsulated with a thermally conductive composite. The coating is derived from ingredients comprising a macrocyclic oligomer and a thermally conductive filler.

In another aspect, the present invention relates to a thermally conductive composite, said composite being derived from ingredients comprising a macrocyclic oligomer and a thermally conductive filler comprising diamond.

### BRIEF DESCRIPTION OF THE DRAWINGS

The understanding of the above mentioned and other advantages of the present invention, and the manner of attaining them, and the invention itself can be facilitated by reference to the following description of the exemplary embodiments of the invention taken in conjunction with the accompanying drawings, wherein:

FIG. 1 is a schematic view of a spacecraft incorporating electronic packages in which thermally conductive composites of the present invention encapsulatingly overcoat microelectronic structures to help dissipate heat from those structures;

FIG. 2 is a schematic view of an alternative embodiment of an electronic package incorporating a thermally conductive composite of the present invention;

FIG. 3 is a schematic view of an alternative embodiment of an electronic package incorporating a thermally conductive composite of the present invention;

FIG. 4 is a schematic view of an alternative embodiment of an electronic package incorporating a thermally conductive composite of the present invention;

FIG. 5 schematically shows three different, representative ways by which a thermal composite coating of the present invention may be formed on representative microelectronic device; and

FIG. 6 shows the device of FIG. 5 interfaced with a wedge clamp.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather, the embodiments are chosen and described so that others skilled in the art can appreciate and understand the principles and practices of the present invention.

The thermally conductive composite of the present invention generally includes a thermally conductive filler incorporated into an organic matrix, wherein the organic matrix is derived from ingredients comprising a macrocyclic oligomer. A macrocyclic oligomer refers to a molecule comprising a ring-shaped moiety in which the ring-shaped moiety is characterized by a degree of polymerization of about 2 or more, typically about 2 to about 20, more typically about 2 to about 12, most typically about 2 to about 6. Preferred embodiments of the macrocyclic oligomer can be caused to ring open and then undergo polymerization with co-reactive molecules under conditions comprising heating the oligomer optionally in the presence of a catalyst.

A representative macrocyclic oligomer may be generically represented by the formula 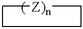
wherein each Z independently may be any divalent moiety, and n is greater than 2 (dimer, trimer, tetramer, etc.), preferably 2 to about 50, more preferably 2 to about 20. Generally, each Z is derived from one or more monomers, oligomers, or polymers, preferably monomers, that can couple to provide the desired degree of polymerization and then further couple to form the ring structure.

A wide variety of macrocyclic oligomers are known. Macrocyclic oligomers and methods of making these compounds have been described, for example, in U.S. Pat. Nos. 6,525,164; 6,436,549; 6,436,548; 6,420,048; 6,420,047; 6,369,157; 6,297,330; 6,187,810; 5,527,976; 5,300,590; 5,191,013; and 4,829,144, each of which is incorporated herein by reference in its entirety. Preferred macrocyclic oligomers include polyester and polycarbonate macrocyclic oligomers. Macrocyclic polyester oligomers are most preferred. Representative embodiments of such macrocyclic polyester oligomers comprise a polyalkylene alkyldicarboxylate macrocyclic oligomer (PAAC), polyalkyl aryldicarboxylate macrocyclic oligomer (PAArC), combinations of these and the like. Such macrocyclic polyester oligomers include alkylene terephthalate moieties such as butylene terephthalate.

Typically, commercially available macrocyclic oligomer materials are supplied in the form of mixtures of macrocyclic polyester oligomers having differing degrees of polymerization. The commercially available materials usually comprise predominantly dimer, trimer, tetramer and pentamer molecules.

In some embodiments, the macrocyclic oligomer may be complexed with one or more metals such as tin, titanium or the like. For instance, such metals can form coordination compounds with carboxylate moieties of PAAC or PAArC. Generally, though, in those modes of practice in which the thermal composite desirably possesses electrically insulating characteristics, macrocyclic oligomer materials with lower ionic content are preferred.

Schematically, a supply of a macrocyclic oligomer may be viewed as containing a plurality of ring-shaped molecules containing at least one linkage, e.g., an ester moiety, carbonate moiety, and/or the like, that can be controllably opened such as by heating to an appropriate temperature. Upon opening, the rings generally become relatively short strands incorporating one or more polymerizable moieties. These polymerizable moieties are co-reactive with complementary moieties on other opened strands, growing strands and/or other molecules. The strands, growing strands, and co-reactive other molecules (if any) thus couple to form higher molecular weight, polymer molecules.

The ring-shaped, oligomeric strands tend to exist as a solid at room temperature but melt to form an extremely low viscosity fluid upon heating. Upon cooling, the material re-solidifies. Interestingly, typical embodiments of the fluid rings tend to not only melt, but also will open and polymerize when heated in the presence of an appropriate catalyst to temperatures moderately higher than the melting temperature of the ring-shaped oligomers. The resultant polymer chains tend to have a melting temperature well above the polymerization temperature such that the polymer chains tend to solidify in situ without requiring cooling as polymerization progresses. Yet, the longer chains themselves in many embodiments retain thermoplastic characteristics, allowing them to be converted to a fluid state when appropriately heated.

A specific example of a macrocyclic polyester oligomer commercially marketed by Cyclics Corporation under the CBT® trade designation illustrates this melting and polymerization behavior. The CBT brand resins are solid at room temperature, and when heated are fully molten above 160° C. (320° F.), with a viscosity in the range of 150 mPa.s (150cP). They drop in viscosity to below 20 mPas (20cP) at 180° C. (355° F.). This initial water-like viscosity allows rapid and excellent wet-out, encapsulation, void filling, etc. at the point of use. When mixed with polymerization catalysts, the cyclic rings open and couple with other open rings or other constituents (i.e., polymerize) to form a high molecular weight thermoplastic polyester polymer or copolymer. Full polymerization can occur in a time range from a few seconds to many minutes depending on the temperature and type of catalyst used. Upon polymerization, the resultant material may solidify in situ without cooling inasmuch as the polymerization reaction can take place at approximately 180° C. (355° F.), which is much below the 220° C. (430° F.) melt temperature of the polymer.

The fluidized oligomer holds a very high weight loading of conductive filler while still retaining desired rheological properties. This allows very high loadings of thermally conductive filler to be used, thus providing unusually high thermal conductivity characteristics while also being isotropic with respect to thermal conductivity in that the composite conducts heat equally well in any direction, e.g., any one or more of the x, y, and z axes. This means the composite is beneficially used in heat intensive, HDI applications and is especially useful for the space industry, where conductive and emissive heat dissipation is crucial to equipment functionality

Preferred thermally conductive composite will have a thermal conductivity constant of at least about 2 W/m*K, and preferably at least about 3 W/m*K, more preferably at least about 4 W/m*K. In the practice of the present invention, thermal conductivity may be determined in accordance with the (ASTM E1461) Laser Flash method.

The thermally conductive filler not only is used to help provide the composite with thermal conductivity characteristics, but also desirably is electrically insulating as well to help preserve desired electronic pathways in electronic devices in which the composite is used. In representative embodiments, the filler will be deemed to be electrically insulating if it has a volume resistivity greater than about 1×10³ ohms, preferably greater than about 1×10⁸ ohms, more preferably greater than about 1×10¹⁶ ohms. In the practice of the present invention, volume resistivity is determined in accordance with the ASTM D991 test method.

The amount of thermally conductive filler(s) incorporated into the thermally conductive composite may vary over a wide range. Representative embodiments may include about 5 volume percent to about 60 volume percent, preferably from about 35 volume percent to about 55 volume percent of filler.

The particle size of the thermally conductive, electrically insulating particles may vary over a wide range. Generally, the particles desirably have an average particle size in the range of from about 0.01 microns to about 1000 microns in the longest aspect of the particle size, preferably about 0.1 to about 200 microns in the longest aspect of the particle size, more preferably about 10 to about 80 microns. Advantageously, the particle size and particle size distribution of the thermally conductive filler tends to be substantially preserved upon melting, cooling, or polymerization of the composite.

Even more preferred filler particles have an average aspect ratio of less than about 4:1 and an average particle size in the long dimension in the range of 10 to 80 micrometers, preferably 20 to 40 micrometers. It is also preferred that the particles have a size distribution such that the percentage of the particles with an average length in the long dimension outside such aspect ratios and length dimensions is as low as possible. These physical characteristics are preferred as a consequence of balancing two competing factors. First, the particles should not be too small. A lower particle size, e.g. nano-scale particles, tend to lack sufficient heat carrying capacity to allow efficient heat transfer. It is believed that this lack of sufficient carrying capacity may be due the relatively lower surface contact among the particles that occurs as smaller particles are used. Yet, the particles should not be too big either. While larger particles permit relatively closer contact among the filler particles, such larger particles might tend to present an abrasive threat to the delicate surfaces of electronic materials. Alternatively, the larger particles may be too large to gain full access to the surfaces of the assembly, and thereby fail to perform. In the practice of the present invention, average particle size may be determined using ASTM Sieve sizes (US standard) or by determining average particle size values using light microscopy in accordance with the ASTM 1070 test method. The use of light microscopy is preferred.

Suitable thermally conductive filler(s) useful in the practice of the present invention generally include thermally conductive particles such as diamond; silver; gold; carbon nanotubes; graphite; carbides such as silicon carbide; nitrides such as boron nitride, silicon nitride, or aluminum nitride; an oxide such as aluminum oxide or beryllium oxide; silicates such as aluminum silicate; and combinations of these, and the like.

For uses of this invention in which it is desired that the composite have electrically insulating properties, particles such as diamond, nitrides, carbides, and/or silicates are preferred.

The thermally conductive filler preferably comprises diamond, either by itself or in combination with one or more other thermally conductive fillers. The diamond filler preferably has an average particle size in the long dimension in the range of 10 to 80 micrometers, preferably 20 to 60 micrometers, and more preferably 20 to 40 micrometers. Diamond filler provides many advantages. Firstly, diamond is an excellent thermal conductor and an excellent electrical insulator. Additionally, diamond is very compatible with macrocyclic oligomers, especially macrocyclic polyester oligomers. The composite retains excellent low viscosity, flow, wettability and other rheological characteristics when diamond is used even at high loadings. Diamond particles also are readily supplied in a suitable particle size range in which the particles are small enough for dense, homogeneous loading in the polymer matrix and yet are large enough to conduct heat effectively. One preferred embodiment of the invention uses particle of the bulk diamond in a size range of 10-20 microns of faceted, low aspect particles. This size range and morphology ensures better contact between particles (An essential feature of filled thermally conductive polymers). It also provides for incorporating as much bulk property as possible without impacting the ability of the particles to pass through narrow dimension of the feature size of the microcircuit assembly (e.g., pitch size between wirebonds).

Other optional ingredients may be included in the thermally conductive composite of the present invention. In addition to the macrocyclic oligomer, the polymer matrix may include one or more other polymer, oligomer, and/or monomeric constituents. Examples include other one or more other polyesters, polyurethanes, poly(meth)acrylates, polycarbonates, combinations of these, and the like. Such other constituents may be thermoplastic or thermosetting and are useful to modulate toughness/resilience or to reduce crystallinity of the polymer matrix. For instance, copolyesters as described in U.S. Pat. No. 6,420,048 may be used in the practice of the present invention.

Other optional ingredients may include one or more of a polymerization catalyst, a colorant such as pigment or dye, an antioxidant, a UV stabilizer, a fungicide, a bactericide, and combinations of the like.

Considerable variation is possible in the form in which the macrocyclic oligomers are combined with filler and other ingredients, if any, of the composite. In one illustrative approach, comminuted oligomer may be physically blended with the other ingredients and used, in essence, as a powder. In other illustrative approaches, the filler and other ingredients can be thoroughly mixed with the fluidized oligomer and then subsequently used in solid and or fluid form.

For example, preforms of a suitable shape and dimension (such as thin disks of a predetermined thickness and diameter to meet the heat spreading properties required by the design) may be used to cover a defined area of a circuit, then heated along with the circuit to the required temperature for flowability (e.g., 160° C.). The fluidized material readily conforms to, underflows and otherwise closely integrates with device features. The material is then solidified via cooling and/or with optional polymerization to thereby encapsulate the coated circuit features. This preform approach can also be done under vacuum for ball grid array and column grid array designs in a process that draws the molten composite under the mounted BGA, yielding an encapsulating undercoat with and without overcoat. The encapsulating material easily matches the shapes and contours of the encapsulated structures and provides three dimensional pathways for carrying heat away from the structures. This approach is especially useful for encapsulating power supplies, which tend to be significant heat sources.

The composite mixture can also be used in the form of a hot-melt spray or thermal spray (i.e., a line of site method that deposits fine palletized particles of oligomer/filler coating as a molten spray to a defined diameter and thickness). Hot-paste deposition may also be used. A typical hot-paste deposition may involve depositing a beaded line of composite using a heated, motor-driven syringe and dispensing reservoir loaded with the composite material. The bead may be applied to the target area using manual or robotic controls. The target substrate may be adjusted in temperature to facilitate this application method.

The composite may be integrated into electronic devices with or without polymerization of the macrocyclic oligomers. If polymerization is desired, the macrocyclic oligomers may be polymerized by heating at a temperature within the range of about 200°-300° C. desirably in the presence of a suitable polymerization catalyst, typically in the amount of about 0.01-2.0 and preferably about 0.05-0.5 mole percent. The resulting polymers generally have weight average molecular weights in the range of about 10,000 to about 100,000.

When in solid form, a composite incorporating relatively greater amounts of the polymerized polymer tends to be more rigid than a composite incorporating relatively greater amounts of the ring-shaped oligomers. Thus, depending upon factors such as the desired manner of intended use and the desired degree of rigidity, one may control the degree and timing of polymerization, if any, of the oligomer via temperature and catalyst selection. For instance, partially rigid embodiments may be more desirable in applications in which the composite will be subjected to vibration, mechanical stresses, or the like. Less rigid embodiments may be more desirable at the time of encapsulation. Some modes of practice may involve starting with a less rigid embodiment to facilitate encapsulation, but then heat treat appropriately during the course of encapsulation or thereafter to convert the material to a more rigid form.

Composites of the present invention provide significant advantages when used for thermal management for electronic packaging, especially with respect to electronic devices incorporated into spacecraft. A key advantage is that the invention enables thermal management properties that dramatically exceed the performance of many conventional composites. Representative embodiments of the invention display high thermal conductivity, e.g., greater than about 1 W/m*K, preferably greater than about 3 W/m*k, and more preferably greater than about 4 W/m*K.

Embodiments of the thermally conductive composite may be electrically insulating to provide pathways to dissipate heat without unduly compromising electrical pathways. Representative embodiments of the invention desirably may have a volume resistivity of greater than 1×10⁷ ohm, preferably greater than about 1×10⁸ ohm, more preferably greater than about 1×10¹⁶ ohm.

Embodiments of the invention may retain their thermoplastic characteristics, even when polymerized. Thus, the composite is reprocessable in such thermoplastic embodiments, providing facile methods to rework hardware incorporating these composites. The composite may also be used as a thermally conductive adhesive to bond components together.

The composite is easily integrated into devices. The low melt viscosity of the oligomer form means high wettability and close integration with the structure into which the composite is incorporated. The composite encapsulates or fills even very fine features when melted, even when highly loaded with filler. The composite is easily solidified by cooling if one desires to avoid polymerization or by appropriate heating to polymerize and solidify in situ. The degree of chain extension easily can be controlled to large degree based upon temperature. The resultant, solidified integrated composite has low voids. This enhances the ability of the composite to dissipate heat without impairment from undue void content. Indeed, the excellent wettability allows close integration to be achieved via gravity alone, so that one need not resort to more technically intensive integration of the composite into a structure.

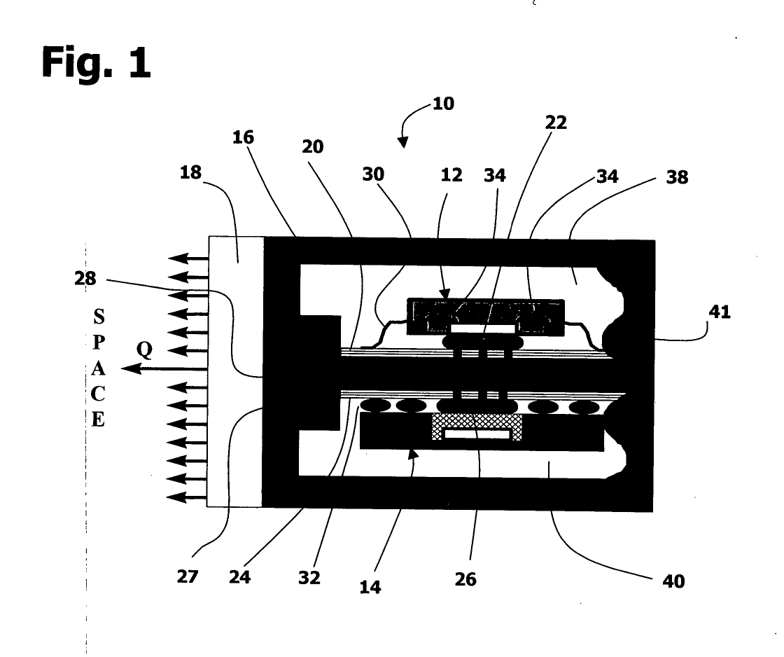

The thermally conductive composite of the invention can be incorporated into a variety of electronic systems in a variety of different ways to facilitate thermal management within such systems. A preferred mode of practice involves encapsulating electronic structures with the composite to provide significant interfacial surface areas by which to conduct heat away from a heat source. This approach is shown in FIG. 1.

FIG. 1 schematically shows a portion of an exemplary spacecraft 10 incorporating principles of the present invention. For purposes of illustration, spacecraft 10 is shown as including a gull-wing PEM or ceramic electronic package 12 and a flip chip package 14. Each electronic package 12 and 14 is in thermal contact with chassis 16 as described further below, and chassis 16 in turn is in thermal contact with a radiator 18 to help dissipate heat Q generated from electronic packages 12 and 14 into space.

Electronic package 12 is attached to a laminated board substrate 20 via a thermally conductive adhesive 22, while electronic package 14 is attached to laminated board substrate 24 via a thermally conductive adhesive 26. Adhesives 22 and 26 may be the same or different. Either adhesive 22 and/or 26 may incorporate a thermally conductive composite of the present invention if desired. Each laminated board 20 and 24 is in thermal contact with heat sink 28, which in turn is in thermal contact with chassis 16, thereby helping to dissipate heat from packages 12 and 14 into space. In a typical embodiment, each laminate board 20 or 24 may be constructed with layers of copper planes that help provide a heat dissipation pathway. Each board 20 or 24 also may be constructed with heavily metallized vias or channels beneath the mounted packages 12 and/or 14 to enhance heat transfer. The heat sink 28 in a typical embodiment may be formed from a thermally conductive material such as a metal alloy, a metal such as aluminum, a ceramic composite, graphite, or the like. Optionally, the heat sink 28 may incorporate embedded heat pipes (not shown) to help enhance heat dissipation to the chassis 16. A clamp such as an aluminum wedge clamp 27 helps to hold heat sink 28 in position. Spacecraft 10 further includes package leads 30, solder joints 32, and wire bonds 34. These interconnect structure are particularly vulnerable to damage if heat is not effectively dissipated from package 12 or package 14.

A thermal composite coating 38 of the present invention encapsulating overcoats electronic package 12, and a thermal composite coating 40 of the present invention encapsulatingly overcoats electronic package 14. Thermal composite coatings 38 and 40 significantly help to conduct heat from packages 12 and 14 to chassis 16. The encapsulating, interfacial coatings 38 and 40 advantageously provide direct, omnidirectional, highly thermally conductive pathways for heat dissipation at very high thermal conductivities. The thermal composite can be formed from a fluid precursor of the composite containing a macrocyclic oligomer and then solidified by cooling and/or polymerization. The resulting solid may undergo very little, some or a higher degree of polymerization as desired. Because of the low viscosity of the fluid, the composite very closely integrates with package features, including filling underfills and small volumes. Very little if any voids typically are present. Shadow 41 designates a random end of chassis 16.

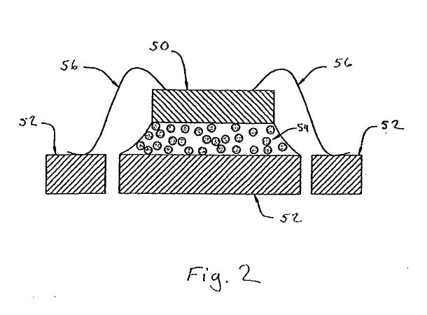

FIG. 2 depicts an integrated circuit device 50 attached to a lead-frame structure 52 through use of thermally conductive composite 54 in accord with the present invention wherein the composite 54 further functions as an adhesive. Electrical interconnection to integrated circuit device 50 is accomplished by conventional wire bonding 56 between integrated circuit device 50 and a lead frame structure 52. The major heat dissipation occurs through the backside of integrated circuit device 50 via thermally conductive composite 54 to the lead frame structure 52 as a heat spreader. Because of a high thermal conductivity of the new thermally conductive composite, heat dissipation is highly efficient.

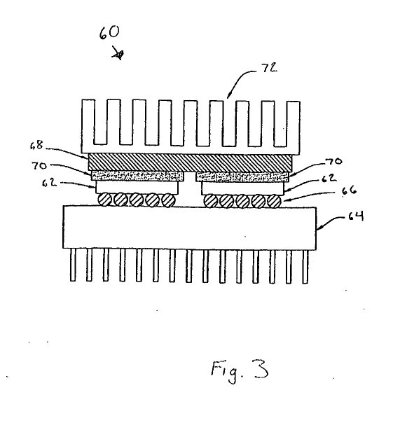

FIG. 3 depicts an electronic packaging module 60 where two integrated circuit devices 62 are mounted to a printed wiring board 64 via solder bumps 66. The back sides of integrated circuit devices 62 are attached to a heat spreader 68 by use of a thermally conductive composite 70 prepared in accord with the present invention. Heat spreader 68 is attached to a heat sink 72. Because of the high thermal conductivity of the present composite material, the thermal resistance between an integrated circuit device and a heat spreader is lower than that realized with the structure where a conventional material, such as a thermal grease, is used.

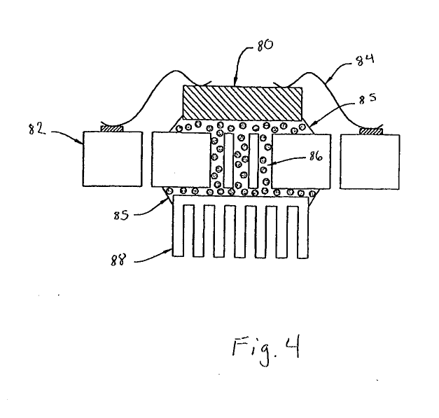

FIG. 4 depicts an application with a printed circuit board or electronic module, which contains thermal vias or plugs within its structure. A high performance, high power, integrated circuit device 80 is electrically connected to a printed circuit board or module 82 via wire bonding 84, while a major thermal path is provided by thermal vias or plugs 86. The thermal vias or plugs 86 are filled with the thermal composite of the present invention. A heat sink 88 is attached to the backside of the printed circuit board or module 82 preferably by use of the same thermal composite material used to form the thermal vias or plugs 86. This structure provides several advantages over the conventional thermal vias or plugs which are formed either by electroplating the via holes or by reflowing solder paste to fill them. The conventional structure tends to require plating as well as additional assembly processes and the use of thermal paste materials to attach a device and a heat sink to the printed circuit board.

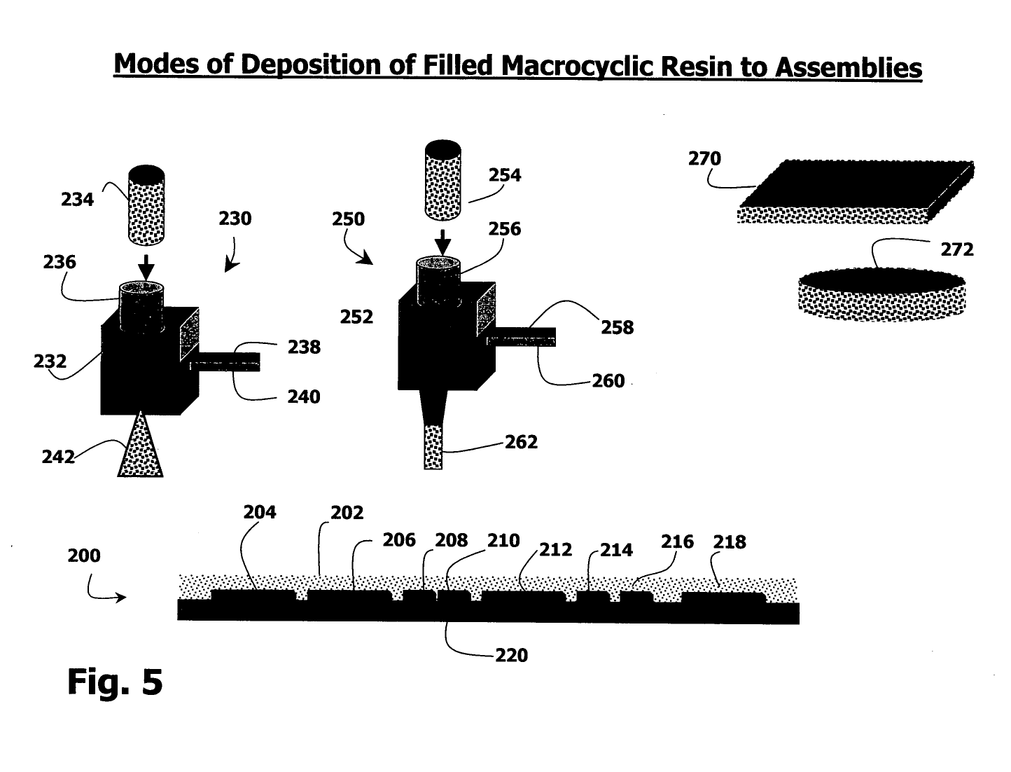

FIG. 5 schematically illustrates representative modes of practicing the present invention. A microelectronic device 200 incorporating a heat dissipating composite coating 202 of the present invention is shown in the lower center region of the figure. Device 200 generally includes a plurality of microelectronic features 204 through 218 formed on a multi-layer PWB or laminate substrate 220. One of these features 206 constitutes a high heat dissipating processor. Heat dissipating composite coating 202 helps to dissipate heat from device 200 in the x, y, and z directions. In typical applications, coating 202 may have a thickness in the range of about 0.3 mils to about 200 mils, more preferably from about 1 mil to about 30 mils, often from about 1 mil to about 5 mils.

FIG. 5 shows three different, representative ways by which coating 202 may be formed on device 200. According to a first technique, the coating 202 may be applied via hot melt spraying via a device such as a conventional hot melt sprayer 230. Sprayer 230 includes a sprayer body 232. It is a distinct advantage of the present invention that the thermal composite of the present invention may be pre-formed into any desired shape. Thus, a thermal composite pre-form of the present invention in the form of cylinder 234 conveniently can be made to fit into feed well 236. Pressurized gas is fed to body via supply line 238 while power to operate sprayer 230 is provided to sprayer 230 via line 240. Sprayer 230 outputs a spray 242 of fluidized composite to allow the fluidized composite to be deposited onto device 200 with high precision. With this approach, there is no need to heat device 200 in order to achieve close integration with the coating 202.

As another option shown in FIG. 5, the coating 202 may be applied via bead deposition using a hot melt gun 250. Gun 250 includes a gun body 252. A thermal composite pre-form of the present invention in the form of cylinder 254 conveniently can be made to fit into feed well 256. Pressurized gas is fed to body via supply line 258 while power to operate sprayer 250 is provided via line 260. Sprayer 250 outputs a bead 262. The bead approach is useful when it is desired to apply the coating 202 only to a well-contained area. The bead approach also would be useful in combination with vacuum impregnation techniques. Depending upon the desired degree of integration between coating 202 and device 200, device 200 may optionally be heated to further fluidized the deposited coating.

As still another option shown in FIG. 5, the thermal composite of the present invention may be provided as a pre-form such as pre-form 270 or 272 and positioned at will to cover a predetermined area of device 200. After positioning the perform 270 or 272, as the case may be, the device 200 is heated as appropriate to attain the desired degree of encapsulation.

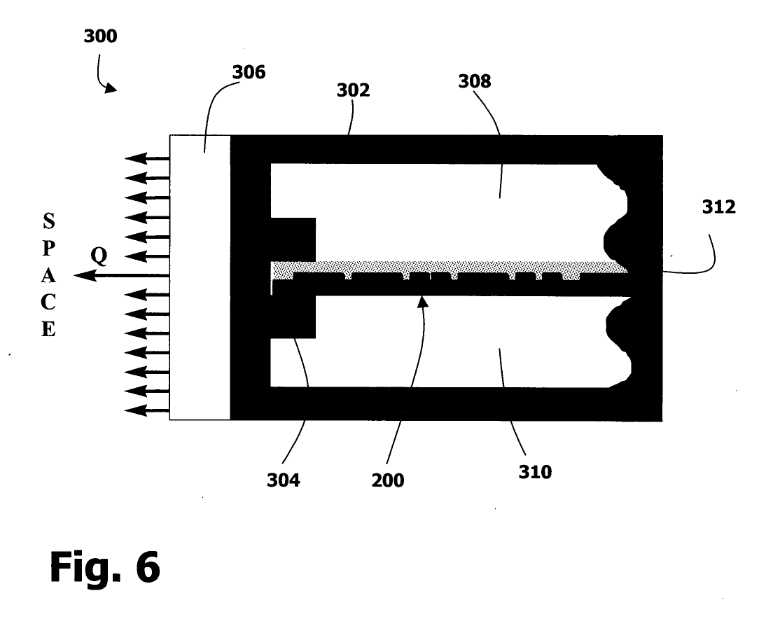

Device 200 is incorporated into spacecraft 300 of FIG. 6. In a manner similar to spacecraft 10 of FIG. 1, spacecraft 300 includes chassis 302, wedge clamp 304, radiator 306, thermal composite 308 and 310 of the present invention, and shadow end 312.

The present invention will be further illustrated in connection with the following examples.

### Example 1

### Preparation Of Thermal Composite Incorporating Silicon-Aluminum Nitride Particles In A Macrocyclic Oligomer (Cyclic Butylenes Terephthalate, “CBT”)

A macrocyclic poly butylene terephthalate (PBT) oligomer obtained from Cyclics Corporation, Schenectady, N.Y., was heated in a metal pan on a hot plate at a temperature above the initial melt point but below that in which further polymerization would occur. When the oligomer was fully melted and clear in color, silicon-aluminum nitride particles were added. The particles were believed to have an average particle size in the range of from about 2 to about 5 mils and enough particles were added to provide a resultant composite including 30% by weight of the particles. The combination of oligomer and particles was stirred with a glass rod until the mixture appeared visually to be homogeneous throughout. To test the ability of this composite to dissipate heat, the resultant composite was collected with a spatula and spread while hot onto on an electronic system including a 10 watt microheater and a series of 36 gauge type K thermocouples mounted on a standard polyamide test SCD board. The composite was worked around the heater to ensure close contact with the device. The composite was allowed to air cool.

This test validated that wattage of the heater could be increase by more than 2× while maintaining temperatures below those obtained with no thermal conductivity coating.

### Example 2

### Preparation of Thermal Composite Incorporating Diamond Particles in A Macrocyclic Oligomer (Cyclic Butylene Terephthalate, “CBT”)

The procedure of Example 1 was followed to apply a composite of the present invention onto a Test SCD memory device (a Single Chip Device test board) to determine electrical compatibility of the composite coating. However, the composite of this example included 40% by weight of diamond particles having an average particle size in the long dimension in the range of from about 2 to about 3 mils. In addition, the material easily flowed around wires and other features without having to work the composite as was done in Example 1.

The resultant coating was tested to evaluate the coating's effect upon the quality of the electrical signal to and from the device. The coated device passed complete parametric testing (hi and low voltage and amperage, along with signal leakage). The thermal conductivity of the 40% diamond filled material was measured using the Flash Laser Technique. The composite coating showed a K value of 4.21 W/mK.

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims.

All patents, patent application documents, and publications cited herein are hereby incorporated by reference in their entireties as if individually incorporated.

What is claimed is:

1. A thermally conductive composite, said composite being derived from ingredients comprising
a. a macrocyclic oligomer; and
b. a thermally conductive filler comprising diamond.

2. The thermally conductive composite of claim 1, wherein the macrocyclic oligomer comprises a plurality of polyester linkages.

3. The thermally conductive composite of claim 1, wherein the macrocyclic oligomer is thermoplastic.

4. The thermally conductive composite of claim 1, wherein the composite comprises a polyester polymer derived from one or more constituents comprising the macrocyclic oligomer.

5. The thermally conductive composite of claim 4, wherein said polyester polymer is thermoplastic.

6. The thermally conductive composite of claim 1, wherein the macrocyclic oligomer comprises a cyclic moiety comprising an alkylene terephthalate.

7. The thermally conductive composite of claim 6, wherein said alkylene terephthalate comprises butylene terephthalate.

8. The thermally conductive composite of claim 1, wherein the filler comprises a nanotube, a nitride, or a combination of these.

9. The thermally conductive composite of claim 1, wherein the filler has an average particle size in the longest dimension in the range of 1 micrometer to about 30 micrometers.

10. The thermally conductive composite of claim 1, wherein the filler has an average particle size in the longest dimension in the range of 10 micrometer to about 80 micrometers.

11. The thermally conductive composite of claim 1, wherein the filler has an average particle size in the longest dimension in the range of 20 micrometer to about 40 micrometers.

12. The thermally conductive composite of claim 1, wherein the composite comprises 0.5 to 60 volume percent of the filler.

13. The thermally conductive composite of claim 1, wherein the filler has a volume resistivity of at least about 1×10³ ohms.

14. The thermally conductive composite of claim 1, wherein the filler has a thermal conductivity of at least about 2 W/m*K.

15. The thermally conductive composite of claim 1, wherein the filler has a thermal conductivity of at least about 3 W/m*K.

16. A method of making a thermally conductive composite, comprising the step of incorporating a thermally conductive filler into a matrix derived from ingredients comprising a macrocyclic oligomer, wherein the thermally conductive filler comprises diamond.

17. The method of claim 16, wherein said incorporating step comprises physically blending the filler and the oligomer.

18. The method of claim 16, wherein said incorporating step comprises melting the oligomer and blending the filler into the melted oligomer.

19. The method of claim 16, further comprising the step of heating the composite under conditions effective to polymerize the oligomer.

20. The method of claim 16, wherein the macrocyclic oligomer comprises a plurality of polyester linkages.

21. The method of claim 16, wherein the macrocyclic oligomer is thermoplastic.

22. The method of claim 16, wherein the composite comprises a polyester polymer derived from one or more constituents comprising the macrocyclic oligomer.

23. The method of claim 22, wherein said polyester polymer is thermoplastic.

24. The method of claim 16, wherein the macrocyclic oligomer comprises a cyclic moiety comprising an alkylene terephthalate.

25. The method of claim 24, wherein said alkylene terephthalate comprises butylene terephthalate.

26. The method of claim 16, wherein the filler further comprises a nanotube, a nitride, or a combination of these.

27. The method of claim 16, wherein the filler has an average particle size in the longest dimension in the range of 1 micrometer to about 30 micrometers.

28. The method of claim 16, wherein the filler has an average particle size in the longest dimension in the range of 10 micrometer to about 80 micrometers.

29. The method of claim 16, wherein the filler has an average particle size in the longest dimension in the range of 20 micrometer to about 40 micrometers.

30. The method of claim 16, wherein the composite comprises 0.5 to 60 volume percent of the filler.

31. The method of claim 16, wherein the filler has a volume resistivity of at least about 1×10³ ohms.

32. The method of claim 16, wherein the filler has a thermal conductivity of at least about 2 W/m*K.

33. The method of claim 16, wherein the filler has a thermal conductivity of at least about 3 W/m*K.

34. An electronic system, comprising:
a) a microelectronic device or power supply component(s);
b) a thermally conductive, composite in thermal contact with the microelectronic device or power supply component(s), said composite being derived from ingredients comprising
i. a macrocyclic oligomer; and
ii. a thermally conductive filler comprising diamond.

35. The system of claim 34, wherein the electronic system constitutes a portion of a spacecraft, a missile, an interceptor, a launch vehicle, and an aircraft.

36. The system of claim 34, wherein the composite encapsulates at least a portion of the microelectronic device or power supply component(s).

37. The system of claim 34, wherein the macrocyclic oligomer comprises a cyclic moiety comprising an alkylene terephthalate.

38. The system of claim 37, wherein said alkylene terephthalate comprises butylene terephthalate.

39. The system of claim 34, wherein the filler further comprises boron nitride.

40. The system of claim 34, wherein the filler is substantially non-acicular.

41. The system of claim 34, wherein the filler has an average particle size in the longest dimension in the range of 1 micrometer to about 30 micrometers.

42. The system of claim 34, wherein the composite comprises 0.5 to 60 volume percent of the filler.

43. A spacecraft comprising a microelectronic device and a thermally conductive, composite in thermal contact with the microelectronic device, said composite being derived from ingredients comprising:
a) a macrocyclic oligomer; and
b) a thermally conductive filler comprising diamond.

44. An electronic system, comprising
a) a heat source comprising a microelectronic device;
b) a heat-dissipating radiator; and
c) a thermal pathway interconnecting the heat source and the radiator, said pathway comprising a thermally conductive, composite comprising
i. a macrocyclic oligomer; and
ii. a thermally conductive filler comprising diamond.

45. A method of making a microelectronic device, comprising the step of encapsulating at least a portion of the device with a thermally conductive, composite, said coating being derived from ingredients comprising a macrocyclic oligomer and a thermally conductive filler comprising diamond.

46. The method of claim 45, wherein said encapsulating step comprises the steps of:
a) placing a pre-form sheet over the device, wherein the sheet comprises the oligomer and the filler;
b) thermally fluidizing the oligomer in the sheet to form a fluidic composite whereby the fluidic composite coats at least a portion of the device;
c) causing the oligomer to polymerize, whereby the composite solidifies and encapsulates at least a portion of the device.

47. The method of claim 45, wherein said encapsulating step comprises the steps of:
a) spraying a fluid composite composition onto at least a portion of the device, said composite composition comprising the oligomer and the filler; and
b) causing the sprayed composition to form a solid encapsulant over at least a portion of the device.

48. The method of claim 45, wherein said encapsulating step comprises the steps of:
a) coating a paste onto at least a portion of the device, said paste comprising the oligomer and the filler; and
b) causing the paste to form a solid encapsulant over at least a portion of the device.

49. A thermally conductive composite, said composite being derived from ingredients comprising
a) a macrocyclic oligomer; and
b) a thermally conductive filler comprising diamond.
